(19) United States
(12) Patent Application Publication
(10) Pub. No.: US 2007/0258312 A1
(43) Pub. Date: Nov. 8, 2007

(54) Memory Cell Array with Multiple Drivers

(75) Inventor: Peter W. Richards, San Francisco, CA (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 11/744,526

(22) Filed: May 4, 2007

Related U.S. Application Data
(60) Provisional application No. 60/798,263, filed on May 5, 2006.

(51) Int. Cl. G11C 8/00

(52) U.S. Cl. 365/230.03

(57) ABSTRACT

Methods and apparatus for selectively updating memory cells of a memory cell array are provided. The memory cells of each row of the memory cell array are provided with a plurality of wordlines. Memory cells of the row are activated and updated by separated wordlines. In an application of display systems using memory cell arrays for controlling the pixels of the display system and pulse-width-modulation (PWM) technique for displaying grayscales, the pixels can be modulated by different PWM waveforms. The perceived dynamic-false-contouring artifacts are reduced thereby. In another application, the provision of multiple wordlines enables precise measurements of voltages maintained by memory cells of the memory cell array.

This application claims priority under 35 USC §119(e)(1) of provisional Application No. 60/798,263, filed May 5, 2006.

### CROSS-REFERENCE TO RELATED REFERENCES

The subject matter of the following publications are incorporated herein by reference in entirety:

| | |
|---|---|
| Serial number: 10/407,061 | filed: Apr. 02, 2003 |
| Serial number: 10/607,687 | filed: Jun. 27, 2003 |
| Serial number: 10/648,608 | filed: Aug. 25, 2003 |
| Serial number: 10/648,689 | filed: Aug. 25, 2003 |
| Serial number: 10/698,290 | filed: Oct. 30, 2003 |
| Serial number: 10/607,687 | filed: Jun. 27, 2003 |
| Serial number: 10/982,259 | filed: Nov. 05, 2004 |
| Serial number: 11/069,408 | filed: Feb. 28, 2005 |
| Serial number: 11/128,607 | filed: May 13, 2005 |

### TECHNICAL FIELD OF THE INVENTION

The present invention is related generally to memory cells, and, more particularly, to memory cell arrays for use in spatial light modulators.

### BACKGROUND OF THE INVENTION

Current memory cell arrays use wordlines and bitlines to read and write the memory cells. Each wordline or bitline is often driven by one single driver. For example, signals in the wordlines or bitlines are delivered in only one direction. This scheme however is fault-intolerant because the wordlines and bitlines are often delicate.

As a way of example, FIG. 1 illustrates a portion of a typical memory cell array in the art. The memory cells (e.g. memory cell 114) are connected bitlines (e.g. 108) and wordlines (106). The wordlines and bitlines are driven by wordline and bitline drivers. For example, wordline 106 is connected to and thus driven by wordline driver 104 of wordline decoder 102. Bitline 108 is connected to and driven by bitline driver 112 of bitline decoder 110. A drawback of this design lies in that signals in a wordline may not be successfully delivered to all memory cells connected to the wordline if the wordline is broken. For example, if wordline 104 is broken at point B, memory cells 115 and 117 are not accessible.

Another drawback of this design is that, regardless of the user's intention, the wordline activates all memory cells of the row simultaneously for writing the intended memory cells during a writing cycle. Consequently, the timing of write events is highly correlated. This time-correlation may cause artifacts, such as dynamic-false-contouring (DFC) in display systems that employ memory cell arrays for controlling the pixels of the display systems and pulse-width-modulation (PWM) technique for displaying gray-scales of images.

Therefore, what is desired is a memory cell array with a robust driving mechanism.

### SUMMARY OF THE INVENTION

In view of the foregoing, the present invention provides a robust memory cell array that is highly fault-tolerant. Such memory is particularly useful for spatial light modulators, and other digital applications.

In an example of the invention, a spatial light modulator device is disclosed, comprising: an array of reflective and deflectable mirror plates; a plurality of addressing electrodes each of which is associated with one of the array of mirror plates; an array of memory cells, each of which is connected to one of the array of addressing electrodes for controlling an electrostatic state of the addressing electrodes; wherein the memory cells are connected to a plurality of bitline and wordlines; and wherein each wordline is connected to two or more wordline drivers that drive the wordline in opposite directions.

In another example of the invention, a method of operating an array of memory cells, each memory cell comprising a transistor and a capacitor, wherein the transistor comprises a source, a gate, and a drain; and wherein the capacitor comprises first and second plates, the method comprising: dividing the memory cells in each row into a plurality of groups; activating the memory cells in different groups with a plurality of different wordlines; writing or reading the memory cells with a plurality of bitlines; alternating a voltage of each one of the second plates of the capacitors with a pump line that connects the second plates of the capacitors so as to obtain a plurality of voltages at a plurality of voltage nodes, each node being formed by a connection of the first plate of the capacitor and the drain of the transistor; wherein the alternating and activating for the same memory cell are synchronized.

In yet another example of the invention, a device comprises: an array of memory cells connected to a plurality of wordlines and bitlines, wherein at least two memory cells in a row are connected to different wordlines; and wherein at least one of the wordlines is connected to first and second wordline drivers for driving said wordline in opposite directions so as to improve the fault tolerance of said wordline.

In yet another example of the invention, a device comprises: an array of memory cells each of which comprising a transistor and a capacitor, wherein the gate of the transistor is connected to one of a plurality of wordlines, wherein the source of the transistor is connected to one of a plurality of bitlines, wherein the drain of the transistor is connected to one of the plates of the capacitor so as to form a voltage node, and wherein the other plate is connected to one of a plurality of pump lines whose voltage is capable of varying in an operation; wherein at least one of the wordlines is connected to first and second wordline drivers for driving said wordline in opposite directions so as to improve the fault tolerance of said wordline.

The objects and advantages of the present invention will be obvious, and in part appear hereafter and are accomplished by the present invention. Such objects of the invention are achieved in the features of the independent claims

### BRIEF DESCRIPTION OF THE DRAWINGS

While the appended claims set forth the features of the present invention with particularity, the invention, together with its objects and advantages, may be best understood from the following detailed description taken in conjunction with the accompanying drawings of which:

FIG. 1 presents a typical memory-cell array in prior art;

FIG. 2 illustrates an example of the invention wherein each wordline is connected to and driven by a plurality of wordlines;

FIG. 3 illustrates an exemplary memory cell that comprises a transistor and a capacitor;

FIG. 4 illustrates another example of the invention wherein each wordline is connected to and driven by a plurality of wordlines; and wherein each row of the memory cell array is connected to multiple wordlines;

FIG. 5 illustrates yet another example of the invention wherein each wordline is connected to and driven by a plurality of wordlines; wherein each row of the memory cell array is connected to multiple wordlines; and each memory cell is connected to a pump line;

FIG. 6 illustrates a portion of a spatial light modulator using the memory cell array of the invention;

FIG. 7 illustrates a cross-sectional view of an exemplary micromirror device of the spatial light modulator of FIG. 6;

FIG. 8 illustrates a perspective view of an exemplary micromirror device having a cross-sectional view of FIG. 7;

FIG. 9 illustrates a perspective view of another exemplary micromirror device having a cross-sectional view of FIG. 7;

FIG. 10 illustrates a perspective view of an exemplary spatial light modulator having an array of micromirror devices showing in FIG. 9;

FIG. 11 illustrates a top view of another exemplary spatial light modulator having an array of micromirror devices showing in FIG. 9;

FIG. 12 and FIG. 13 illustrate top views of yet another exemplary spatial light modulator having an array of micromirror devices showing in FIG. 9;

FIG. 14a demonstrates a 4-bits binary-weighted waveform format;

FIG. 14b and FIG. 14c illustrate two exemplary binary-weighted pulse-width-modulation waveforms generated according to the waveform format in FIG. 14a;

FIG. 15 shows another exemplary binary-weighted waveform format according to another embodiment of the invention;

FIG. 16a and FIG. 16b present two exemplary waveforms generated according to the waveform format in FIG.15;

FIG. 17a presents yet another exemplary waveform format according to yet another embodiment of the invention;

FIG. 17b presents a further exemplary waveform format according to a further embodiment of the invention;

FIG. 18 illustrates an exemplary projection system in which the invention can be implemented;

FIG. 19 illustrates an exemplary projection system in which the invention can be implemented;

FIG. 20 illustrates an exemplary projection system in which the invention can be implemented; and

FIG. 21 illustrates an exemplary LED array usable in the projection system of FIG. 20.

### DETAILED DESCRIPTION OF THE INVENTION

In view of the foregoing, the present invention provides a robust memory cell array. The memory cells are connected to wordlines and bitlines for reading and writing memory cells. Each wordline is driven by two wordline drivers that deliver wordline signals in opposite directions. Such configuration enables wordline signals to be properly delivered to the memory cells connected thereto even if the wordline has a broken point. Such configuration also improves the signal transmission rate in the wordline, and the accessing speed to the memory cells. The bitlines each may or may not be configured the same as the wordlines.

As an alternative feature, the memory cells in each row of the memory cell array are grouped into groups, such an even and odd number positioned memory cells in the row of the array. The memory cells in the row can be activated using different wordlines. Specifically, the memory cells in the same group can be activated with the same wordline; while the memory cells in different groups are activated using a different wordline.

In addition to wordlines and bitlines, the memory cells can be connected to pump lines whose voltages vary over time. In a particular example wherein each memory cell comprises a transistor and a capacitor, the source of the transistor is connected to one of the bitlines. The gate of the transistor is connected to a bitline; and the drain of the transistor is connected to a plate of the capacitor so as to form a voltage node. The other plate of the capacitor is connected to the pump line. The pump line may or may not be driven by two pump line drivers that deliver the pump line signals at opposite directions. When multiple wordlines are used to activate the memory cells in a row, the pump line, if provided, is desired to be synchronized to the wordline connected to the same memory cell.

The memory cell array of the invention has many applications, one of which is in micromirror-based spatial light modulators. Such a spatial light modulator comprises an array of reflective and deflectable mirror plates. Each mirror plate is associated with an addressing electrode whose voltage is determined by image data derived from the desired image. The addressing electrodes each are connected to a voltage node of a memory cell of the memory cell array, such as the node connecting the drain of the transistor and a capacitor plate in the above example. With this configuration, the mirror plate can be activated by an electrostatic field established between the mirror plate and addressing electrode associated with the mirror plate. When the memory cells are provided with multiple wordline drivers for each row of the array, artificial effects, such as the false-dynamic-contour, in traditional memory cells where the memory cells of a row are activated by only one wordline, can be avoided. In the following, the present invention will be discussed with reference to particular examples. It will be understood by those skilled in the art that the following discussion is for demonstration purposes, and should not be interpreted as a limitation. Instead, other variations without departing from the spirit of the invention are also applicable.

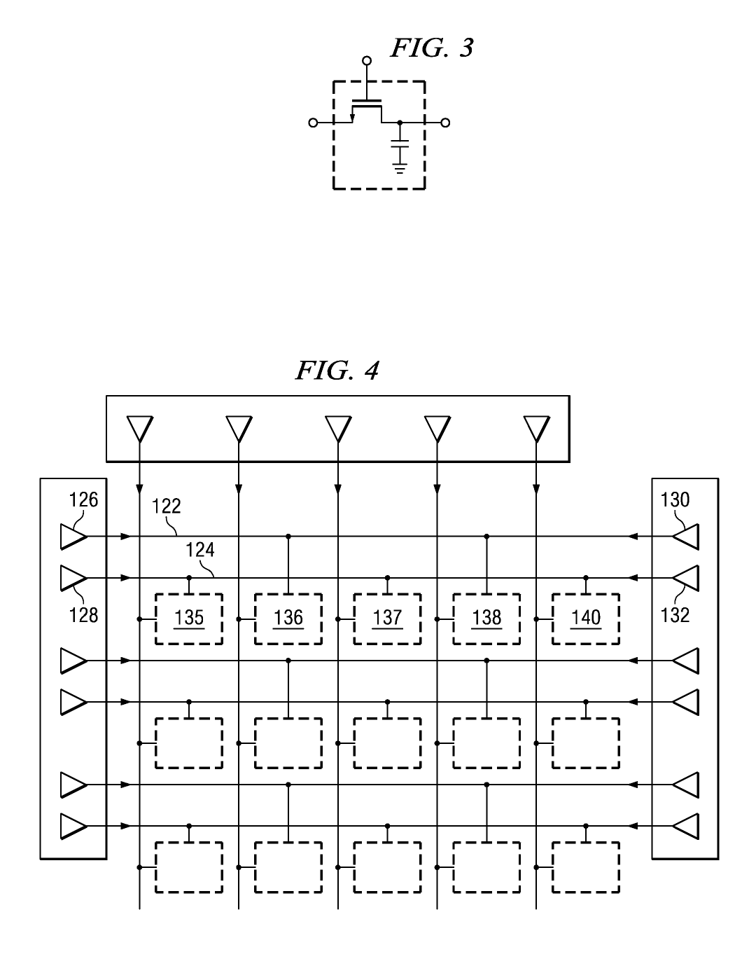

Turning to the drawings, FIG. 2 illustrates an exemplary memory cell array of the invention. For demonstration purposes, only 5×3 memory cells are illustrated. In general, the number of memory cells of the array is determined by the specific applications. For example, the array may comprise 640×480 (VGA) or higher, such as 800×600 (SVGA) or higher, 1024×768 (XGA) or higher, 1280×1024 (SXGA) or higher, 1280×720 or higher, 1400×1050 or higher, 1600×1200 (UXGA) or higher, and 1920×1080 or higher memory cells, when used in projection systems, which will be discussed afterwards with reference to FIG. 10 to FIG. 21. The memory cells can be any type of memory cells, such as DRAM, SRAM, and latch. FIG. 3 illustrates another exemplary memory cell.

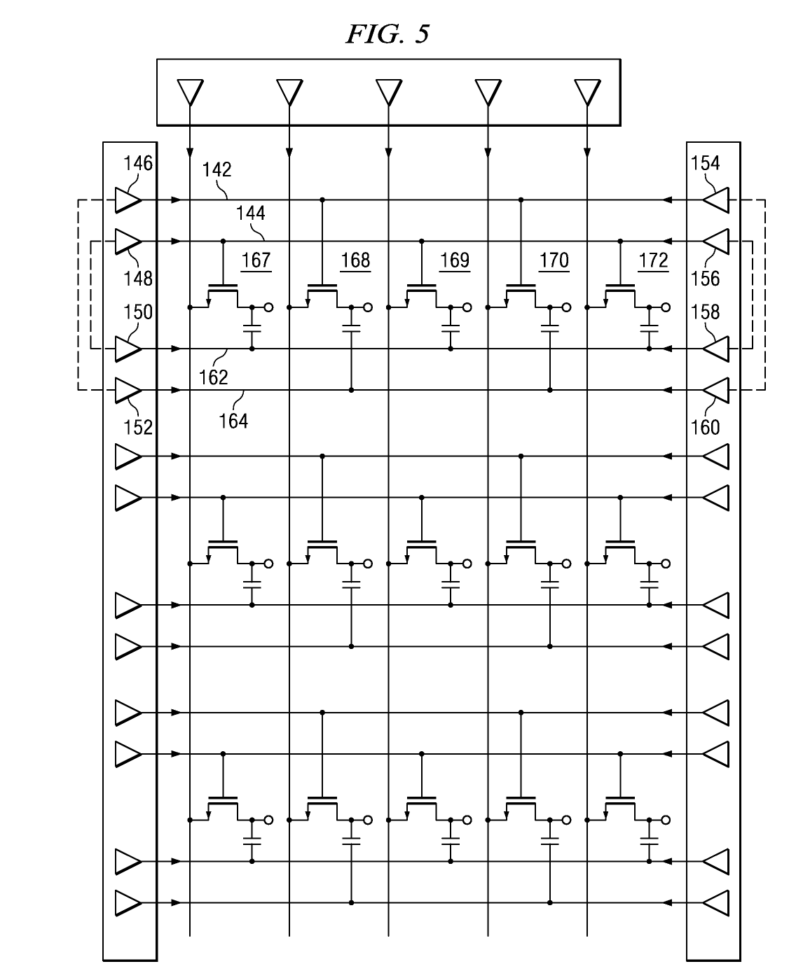

Referring to FIG. 3, the memory cell, which is often referred to as ITIC, comprises a transistor and a capacitor. The source of the transistor is to be connected to a bitline, and the gate is to be connected to a wordline. The drain and one plate of the capacitor are connected to form a voltage node. The other plate of the capacitor can be connected to a fixed voltage, such as ground. Alternatively, the other plate of the capacitor can be connected to a voltage source that varies over time during operation—such as a pump line, which will be discussed afterwards with reference to FIG. 5.

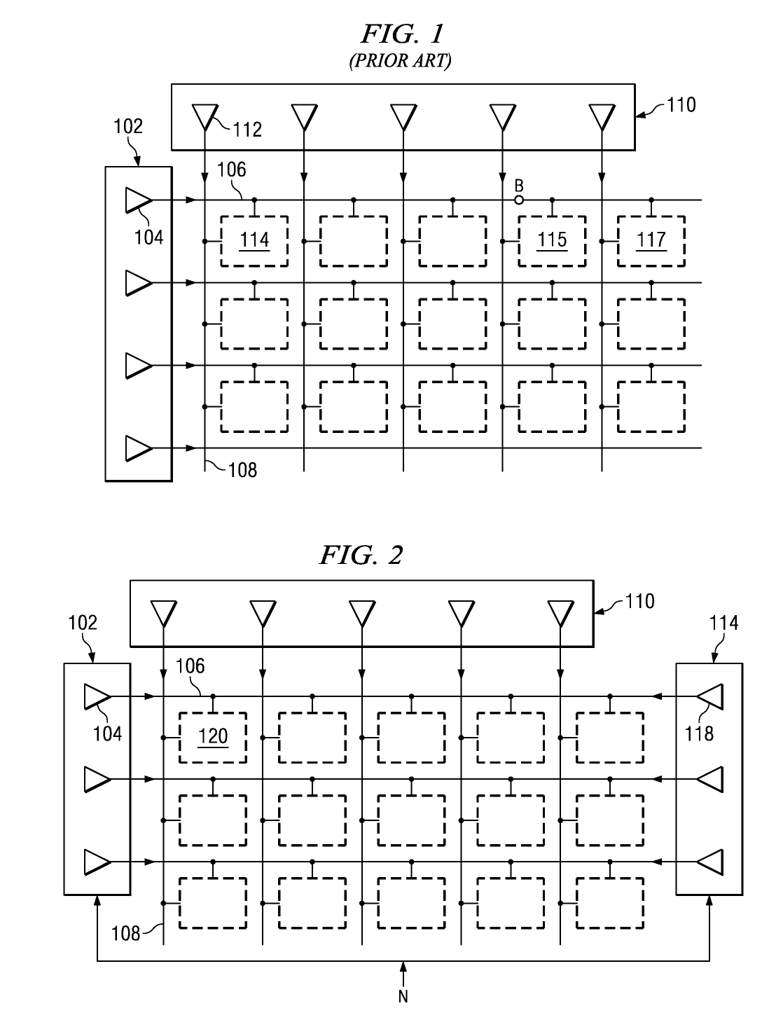

Turning back to FIG. 2, the memory cells are connected to wordlines and bitlines for updating the memory cells. For example, memory cell 120 is connected to wordline 106 and bitline 108. Typically, the wordlines activate the memory cells connected thereto; and the bitlines read and write the activated memory cells. In accordance with an example of the invention, each wordline is driven by multiple wordline drivers. For example, wordline 106 is connected to and simultaneously driven by wordline driver 104 of wordline decoder 102 and wordline driver 118 of wordline decoder 114. Specifically, the paired wordline drivers 104 and 118 simultaneously deliver activation signals for wordline 106 but in opposite directions. As a consequence, each one of the drivers 104 and 118 activates a portion of the memory cells in the row. This configuration and activation mechanism has many advantages. For example, even if the wordline has a broken point, as that in FIG. 1, all memory cells can still be accessed and activated. Therefore, the fault-tolerance is improved. For another example, because the memory cells in the row are activated simultaneously by the wordline drivers, the electronic states of the memory cells and the voltage state of the wordline can be stabilized faster than wordline and memory cells with only one wordline driver. To guarantee the simultaneous cooperation of the paired wordline drivers (e.g. 104 and 118), the paired wordlines can be configured to share a common signal source, such as signal source N, as shown in the figure. Alternatively, each bitline can be driven by more than one bitline driver, even though the figure shows that each wordline is driven by one of a set of bitline drivers of bitline decoder 110.

In accordance with another example of the invention, the memory cells of a row of the memory cell array can be driven by multiple wordlines with each wordline being driven by multiple wordline drivers, as shown in FIG. 4.

Referring to FIG. 4, memory cells 135, 136, 137, 138, and 140 in an exemplary row of the memory cell array are connected to separate wordlines 122 and 124, wherein different wordlines are connected to different groups of memory cells. In this particular example, even and odd numbered memory cells are alternatively connected to wordlines 122 and 124. Thereby, adjacent memory cells of the row can be activated separately. The phase-coherence in memory cells wherein memory cells in a row are connected to single wordline can be removed. The phase-coherence induced artificial effect, such as the dynamic-false-contour can be eliminated. Of course, the memory cells in a row can be connected to other desired number of wordlines. The memory cells in the row can be connected to the wordlines according to any desired schemes. In general, the memory cells in a row can be grouped into memory cell groups as desired. The memory cells in the same group can be connected to the same wordline, while the memory cells in different groups can be connected to different wordlines, as set forth in U.S. Pat. No. 6,856,447, issued Feb. 15, 2005, the subject matter being incorporated herein by reference in entirety.

Each wordline is driven by multiple wordline drivers. For example, wordline 122 is connected to wordline drivers 126 and 130; and wordline 124 is connected to and driven by wordline drivers 128 and 132. Wordline drivers 126 and 130 are paired so as to simultaneously activate wordline 122. Wordline drivers 128 and 132 are paired so as to simultaneously activate wordline 124. As an alternative feature, each bitline may or may not be connected to and driven by multiple bitline drivers. Specifically, each bitline can be driven by multiple bitline drivers in opposite directions so as to improve the fault-tolerance and increase the stabilization rate of the bitlines. When each bitline is connected to multiple bitline drivers, each wordline may or may not be connected to and driven by multiple wordline drivers.

As another example of the invention, each memory cell can be connected to a pump line so as to boost the output voltage, as set forth in U.S. Pat. No. 7,012,592 issued Mar. 14, 2006, the subject matter being incorporated herein by reference.

FIG. 5 demonstratively illustrates an exemplary array of charge-pump-memory cells. Specifically, the charge-pump-memory-cell comprises a transistor and a capacitor. The source and gate of the transistor are connected to bitline and wordline, respectively. The drain of the transistor is connected to one plate of the capacitor, while the other plate of the capacitor is connected to a pump line. In accordance with an example of the invention, each pump line is drive by multiple pump line drivers that deliver pump line signals in opposite direction. The memory cells of the row may or may not be provided with multiple wordlines, and each wordline may or may not be driven by multiple wordline drivers. Similarly, the memory cells in a column may or may not be connected to multiple bitlines; and each bitline may or may not be driven by multiple bitline drivers.

In the example as shown in FIG. 5, charge-pump-memory-cells 167, 168, 169, 170, and 172 in a row of the array are alternatively connected to wordlines 142 and 144. These charge-pump-memory-cells are also connected to pump lines 162 and 164. It is noted that the connection of the pump lines to the cells is associated with the connection of the wordlines. Specifically, the memory cells connected to the same wordline are connected to the same pump line; and such pump line is coordinated with such wordline. For example, wordline 142 is connected to cells 168 and 170. These memory cells 168 and 170 are connected to pump line 164. Pump line 164 and wordline 142 are paired and coordinated during operation. Similarly, wordline 144 connected to memory cells 167, 169, and 172 is paired and coordinated with pump line 162 connected to the same group of memory cells comprising 167, 169, and 172.

Pump lines 162 and 164 are driven by paired drivers 150 and 158, and 152 and 160, respectively. Wordline 142 is driven by drivers 146 and 154; and wordline 144 is driven by paired drivers 148 and 156. Alternatively, each bitline can be driven by multiple drivers in opposite directions, which is not shown in the figure.

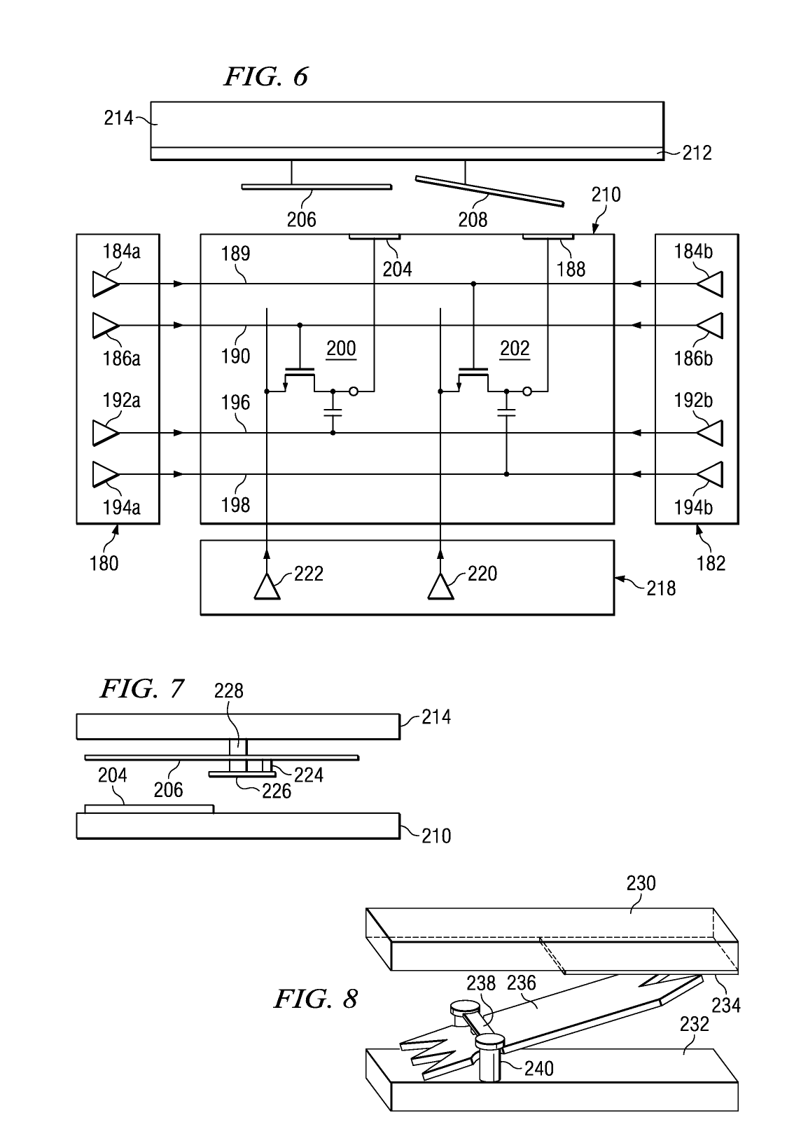

The memory cells as discussed above and variations have many applications, one of which is in micromirror array devices. Referring to FIG. 6, a cross-sectional view of a portion of an exemplary micromirror array is illustrated therein. For simplicity and demonstration purposes, only two micromirror devices of the micromirror array are illustrated.

In the example as shown in FIG. 6, an array of reflective and deflectable mirror plates 206 and 208 are formed on substrate 214 that is transmissive to the desired light, such as visible light. Addressing electrodes 204 and 188 are disposed proximately to and associated with mirror plates 206 and 208, respectively. Each addressing electrode is connected to a voltage output node of a memory cell. For example, addressing electrode 204 is connected to the voltage node formed by the connection of the drain of the transistor and one plate of the capacitor of memory cell 200. Addressing electrode 188 is connected to the voltage node formed by the connection of the drain of the transistor and one plate of the capacitor of memory cell 202. Voltages of the addressing electrodes can thus be controlled by the information stored in memory cells 200 and 202. Specifically, memory cells 200 and 202 can be activated independently by wordlines 189 and 190. Such activations are accomplished by wordline drivers 184a and 184b; and 186a and 186b, respectively. The activated memory cells are then written or read through the bitlines connected thereto, the bitlines being driven by bitline drivers 222 and 220. In cooperation with the activation of the memory cells, pump lines deliver pump line signals to the memory cells. Specifically, when memory cell 200 is to be activated, a wordline activation signal is delivered to memory cell 200 through wordline 190 that is driven by drivers 186a and 186b. At the same time, a pump line signal is delivered to memory cell 200 through pump line 196 that is driven by pump line drivers 192a and 192b. Reading and writing memory cell 200 can be accomplished through bitline connected thereto that is driven by bitline driver 222 of bitline decoder 218.

In operation, when a mirror plate, such as mirror plate 206 is expected to be at a natural resting state, such as the OFF state as shown in the figure, memory cell 200 associated with mirror plate 206 is set to a state such that addressing electrode 204 is at a voltage state resulting in an electrostatic field between mirror plate 206 and addressing electrode 204 being substantially zero, or a value that is insufficient to move mirror plate 206. When a mirror plate, such as mirror plate 208 is expected to be at a deflected state (e.g. the ON state), an electrostatic field is established between mirror plate 208 and addressing electrode 188 with an amplitude sufficient to move the mirror plate to the desired deflected state. Such electrostatic field can be accomplished by updating memory cell 202 with wordline 189 through wordline drivers 184a and 184b, pump line 196 through pump line drivers 192a and 192b, and the bitline connected to memory cell 202 through bitline driver 220. The deflected mirror plate (e.g. 208) can be released from the deflected state to the natural resting state by removing the electrostatic field between mirror plate 208 and addressing electrode 188 by updating the voltage in memory cell 202 through wordline 189, pump line 198, and the bitline connected thereto. As an alternative feature, transparent electrode 212 can be formed on substrate 214 for resetting the mirror plates to the natural resting state by pulling the mirror plate towards substrate 214.

In the above example as shown in FIG. 6, the mirror plates are formed on a substrate other than the substrate (e.g. substrate 210 that is a semiconductor substrate) on which the addressing electrodes and memory cells are formed. In an alternative example of the invention, the mirror plates, addressing electrodes, and memory cells can be formed on the same substrate, such as semiconductor substrate 210.

The micromirror device of FIG. 6 may have different configurations, one of which is illustrated in FIG. 7. Referring to FIG. 7, the micromirror device comprises reflective deflectable mirror plate 206 that is attached to deformable hinge 226 via hinge contact 224. The deformable hinge, such as a torsion hinge is held by a hinge support that is affixed to post 228 on light transmissive substrate 214. Addressing electrode 204 is disposed on semiconductor substrate 210, and is placed proximate to the mirror plate for electrostatically deflecting the mirror plate. Other alternative features can also be provided. For example, a stopper can be provided for limiting the rotation of the mirror plate when the mirror plate is at the desired angles, such as the ON state angle. The ON state angle is preferably 10° degrees or more, 12° degrees or more, or 14° degrees or more relative to substrate 214. For enhancing the transmission of the incident light through the light transmissive substrate 214, an anti-reflection film can be coated on the lower surface of substrate 214. Alternatively the anti-reflection film, a light transmissive electrode can be formed on the lower surface of substrate 214 for electrostatically deflecting the mirror plate towards substrate 214. An example of such electrode can be a thin film of indium-tin-oxide. The light transmissive electrode can also be a multi-layered structure. For example, it may comprise an electrically conductive layer and electrically non-conductive layer with the electrically conductive layer being sandwiched between substrate 214 and the electrically non-conductive layer. This configuration prevents potential electrical short between the mirror plate and the electrode. The electrically non-conductive layer can be SiOₓ, TiOₓ, SiNx, and NbOₓ, as set forth in U.S. patent application Ser. No. 11/102,531 filed Apr. 8, 2005, the subject matter being incorporated herein by reference. In other embodiments of the invention, multiple addressing electrodes can be provided for the micromirror device, as set forth in U.S. patent application Ser. No. 10/437,776 filed May 13, 2003, and Ser. No. 10/947,005 filed Sep. 21, 2004, the subject matter of each being incorporated herein by reference in entirety. Other optical films, such as a light transmissive and electrically insulating layer can be utilized in combination with the light transmissive electrode on the lower surface of substrate 214 for preventing possible electrical short between the mirror plate and light transmissive electrode.

In the example shown in FIG. 7, the mirror plate is associated with one single addressing electrode on substrate 210. Alternatively, another addressing electrode can be formed on substrate 210, but on the opposite side of the deformable hinge.

The micromirror device as show in FIG. 7 is only one example of many applicable examples of the invention. For example, in the example as shown in FIG. 7 the mirror plate is attached to the deformable hinge such that the mirror plate rotates asymmetrically. That is the maximum rotation angle (e.g. the ON state angle) achievable by the mirror plate rotating in one direction (the direction towards the ON state) is larger than that (e.g. the OFF stat angle) in the opposite rotation direction (e.g. the direction towards the OFF state). This is accomplished by attaching the mirror plate to the deformable hinge at a location that is not at the center of the mirror plate such that the rotation axis of the mirror plate is offset from a diagonal of the mirror plate. However, the rotation axis may or may not be parallel to the diagonal. Of course, the mirror plate can be attached to the deformable hinge such that the mirror plate rotates symmetrically. That is the maximum angle achievable by rotating the mirror plate is substantially the same as that in the opposite rotation direction.

The mirror plate of the micromirror shown in FIG. 7 can be attached to the deformable hinge such that the mirror plate and deformable hinge are in the same plane. In an alternative embodiment of the invention, the deformable hinge can be located in a separate plane as the mirror plate when viewed from the top of the mirror plate at a non-deflected state, which will not be discussed in detail herein.

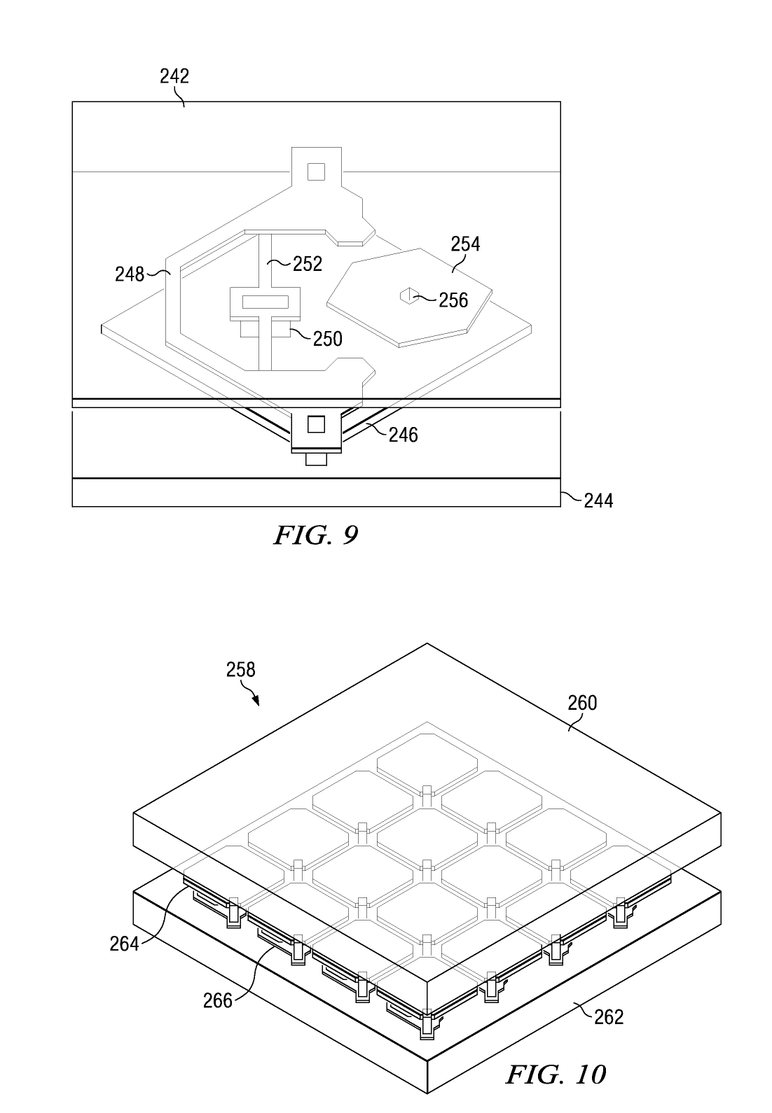

In the following, selected exemplary micromirror devices having the cross-sectional view of FIG. 7 will be discussed with reference to FIG. 8 and FIG. 9. It will be immediately understood by those skilled in the art that the following discussion is for demonstration purposes only and is not intended to be limiting. Instead, any variations without departing from the spirit of the invention are also applicable.

Referring to FIG. 8, a perspective view of an exemplary micromirror device in which embodiments of the invention are applicable is illustrated therein. The micromirror device comprises substrate 232 that is a light transmissive substrate such as glass, quartz, and sapphire and semiconductor substrate 230, such as silicon substrate. Deflectable and reflective mirror plate 236 is spaced apart and attached to deformable hinge 238 via a hinge contact. The deformable hinge is affixed to and held by posts 240. The semiconductor substrate has addressing electrode 234 for deflecting the mirror plate. A light blocking pad can be alternatively formed between the surface of post 240 and substrate 232 for reducing unexpected light scattering from the exposed surface of the posts.

The deflectable and reflective mirror plate can be a multilayered structure. For example, the mirror plate may comprise an electrical conducting layer, a reflective layer that is capable of reflecting 85% or more, or 90% or more, or 85% or more, or 99% or more of the incident light (e.g. incident visible light), a mechanical enhancing layer that enhances the mechanical properties of the mirror plate. An exemplary mirror plate can be a multilayered structure comprising a SiO₂ layer, an aluminum layer, a titanium layer, and a titanium nitride layer. When aluminum is used for the mirror plate; and amorphous silicon is used as the sacrificial material, diffusion between the aluminum layer and the sacrificial material may occur. This can be avoided by depositing a barrier layer therebetween.

Another exemplary micromirror device having a cross-sectional view of FIG. 7 is illustrated in its perspective view in FIG. 9. Referring to FIG. 9, deflectable reflective mirror plate 246 with a substantially square shape is formed on light transmissive substrate 244, and is attached to deformable hinge 252 via hinge contact 250. The deformable hinge is held by hinge support 248, and the hinge support is affixed and held by posts on the light transmissive substrate. For electrostatically deflecting the mirror plate, an addressing electrode (not shown in the figure for simplicity purposes) is fabricated in the semiconductor substrate 242. For improving the electrical coupling of the deflectable mirror plate to the electrostatic field, extending metallic plate 254 can be formed on the mirror plate and contacted to the mirror plate via post 256. A light blocking pad can be alternatively disposed between the surface of the post and substrate 244 so as to reduce unexpected light scattering from the post. The light blocking pad can also be deployed in a way so as to block light scattered from other portions of the micromirror, such as the tips (or the corners) of the mirror plate of the micromirror, and the exterior surfaces (e.g. the walls) of the posts.

The mirror plate is preferably attached to the deformable hinge asymmetrically such that the mirror plate can be rotated asymmetrically for achieving high contrast ratio. Similar to that shown in FIG. 8, the deformable hinge is preferably formed beneath the deflectable mirror plate in the direction of the incident light so as to avoid unexpected light scattering by the deformable hinge. For reducing unexpected light scattering of the mirror plate edge, the illumination light is preferably incident onto the mirror plate along a corner of the mirror plate.

Referring to FIG. 10, an exemplary spatial light modulator having an array of micromirrors of FIG. 9 is illustrated therein. For simplicity purposes, only 4×4 micromirrors are presented. In general, the micromirror array of a spatial light modulator consists of thousands or millions of micromirrors, the total number of which determines the resolution of the displayed images. For example, the micromirror array of the spatial light modulator may have 800×600 (SVGA) or higher, 1024×768 (XGA) or higher, 1280×1024 (SXGA) or higher, 1280×720 or higher, 1400×1050 or higher, 1600×1200 (UXGA) or higher, and 1920×1080 or higher, micromirror devices. In other applications, the micromirror array may have less number of micromirrors.

In this example, the array of deflectable reflective mirror plates 264 is disposed between light transmissive substrate 260 and semiconductor substrate 262 having formed thereon an array of addressing electrodes 266 each of which is associated with a mirror plate for electrostatically deflecting the mirror plate. The posts of the micromirrors can be covered by light blocking pads for reducing expected light scattering from the surfaces of the posts.

In operation, the illumination light passes through the light transmissive substrate and illuminates the reflective surfaces of the mirror plates, from which the illumination light is modulated. The illumination light incident onto the areas corresponding to the surfaces of the posts are blocked (e.g. reflected or absorbed depending upon the materials of the light blocking pads) by the light blocking pads. The reflected illumination light from the mirror plates at the ON state is collected by the projection lens so as to generate a “bright” pixel in the display target. The reflected illumination from the mirror plates at the OFF state travels away from the projection lens, resulting in the corresponding pixels imagined at the display target to be “dark.”

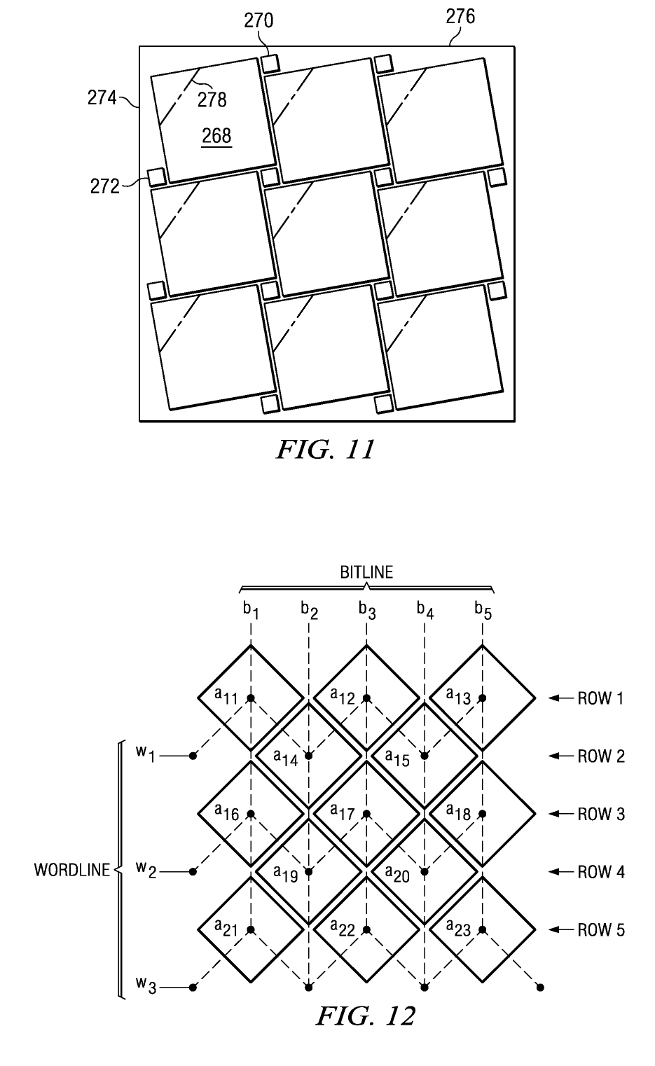

The micromirrors in the micromirror array of the spatial light modulator can be arranged in alternative ways, another one of which is illustrated in FIG. 11. Referring to FIG. 11, each micromirror is rotated around its geometric center an angle less than 45° degrees. The posts (e.g. 270 and 272) of each micromirror (e.g. mirror 268) are then aligned to the opposite edges of the mirror plate. No edges of the mirror plate are parallel to an edge (e.g. edges 274 or 276) of the micromirror array. The rotation axis (e.g. axis 278) of each mirror plate is parallel to but offset from a diagonal of the mirror plate when viewed from the top of the mirror plate at a non-deflected state.

FIG. 12 illustrates the top view of another micromirror array having an array of micromirrors of FIG. 11. In this example, each micromirror is rotated 45° degrees around its geometric center. For addressing the micromirrors, the bitlines and wordlines are deployed in a way such that each column of the array is connected to a bitline but each wordline alternatively connects micromirrors of adjacent rows. For example, bitlines b₁, b₂, b₃, b₄, and b₅ respectively connect micromirror groups of (a₁₁, a₁₆, and a₂₁), (a₁₄ and a₁₉), (a₁₂, a₁₇, and a₂₂), (a₁₅ and a₂₀), and (a₁₃, a₁₈, and a₂₃). Wordlines w₁, w₂, and w₃ respectively connect micromirror groups (a₁₁, a₁₄, a₁₂, a₁₅, and a₁₃), (a₁₆, a₁₉, a₁₇, a₂₀, and a₁₈), and (a₂₁, a₂₂, and a₂₃). With this configuration, the total number of wordlines is less than the total number of bitlines.

For the same micromirror array, the bitlines and wordlines can be deployed in other ways, such as that shown in FIG. 13. Referring to FIG. 13, each row of micromirrors is provided with one wordline and one bitline. Specifically, bitlines b₁, b₂, b₃, b₄ and b₅ respectively connect column 1 (comprising micromirrors a₁₁, a₁₆, and a₂₁), column 2 (comprising micromirrors a₁₄ and a₁₉), column 3 (comprising micromirrors a₁₂, a₁₇, and a₂₂), column 4 (comprising micromirrors a₁₅ and a₂₀), and column 5 (comprising micromirrors a₁₃, a₁₈, and a₂₃). Wordlines WL₁, WL₂, WL₃, WL₄, and WL₅ respectively connect row 1 (comprising micromirrors all, a₁₂, and a₁₃), row 2 (comprising micromirrors a₁₄ and a₁₅), row 3 (comprising micromirrors a₁₆, a₁₇, and a₁₈), row 4 (comprising micromirrors a₁₉ and a₂₀) and row 5 (comprising micromirrors a₂₁, a₂₂, and a₂₃).

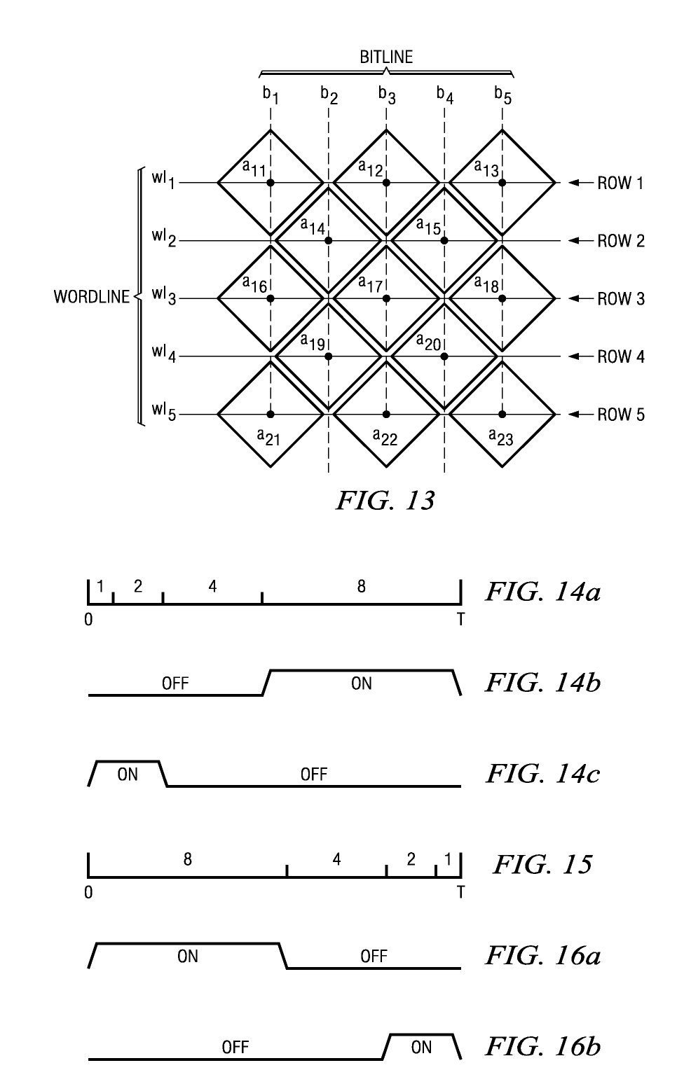

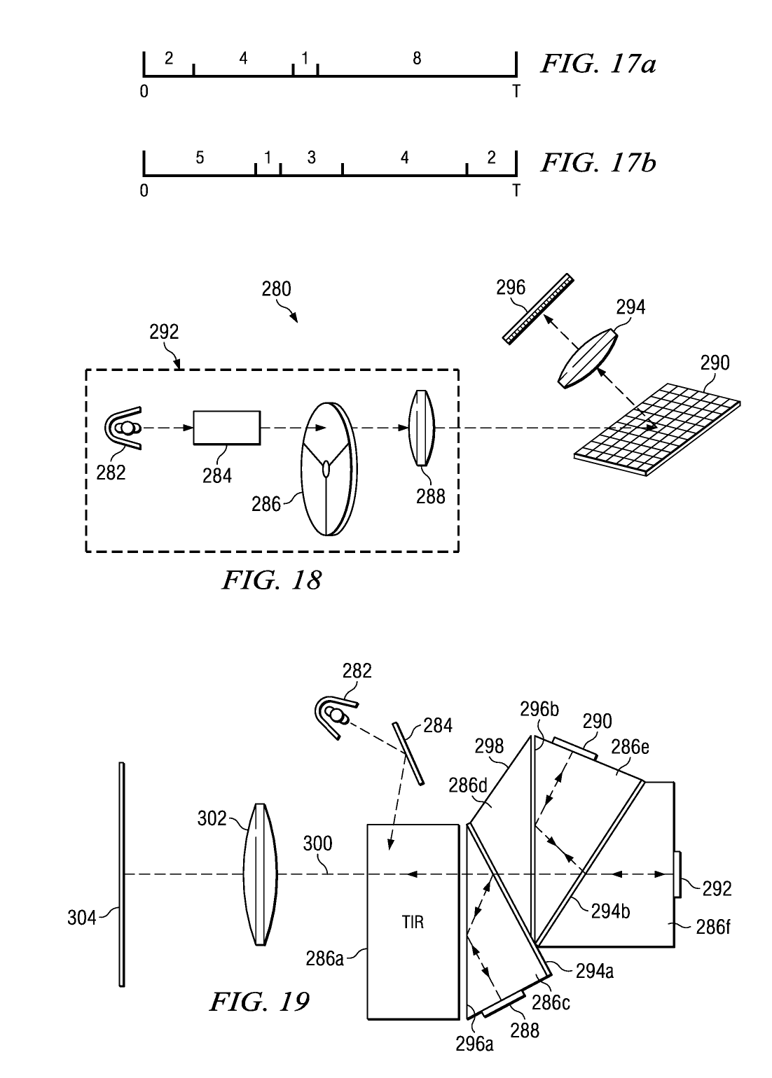

In order to simulate grayscales of the moving object, PWM waveforms are generated according to the predefined PWM waveform formats and the desired grayscales. In the embodiment of the invention, at least two binary-weighted PWM waveform formats are defined. A first PWM waveform format is a binary-weighted waveform format starting from the least significant bit (LSB) and ending at the most significant bit (MSB), as shown in FIG. 14a. A second PWM waveform format is a binary-weighted waveform format starting from the MSB and ending at the LSB, as shown in FIG. 15. Though preferred, other suitable waveform formats could also be applied. In particular, the waveform format can be a binary-weighted format with the binary weights randomly arranged, as shown in FIG. 17a. Alternatively, the waveform format can be non-binary weighted format, as shown in FIG. 17b.

Given the defined waveform formats, PWM waveforms are generated according to the desired grayscales. For example, PWM waveforms shown in FIGS. 14b and 14c are generated based on the defined format of FIG. 14a. And PWM waveforms shown in FIG. 16a and 16b are generated based on the defined format of FIG. 15. Referring to FIG. 14b, the waveform is in the “OFF” state during the first 7 (7=1+2+) segments of the frame duration T and turned “ON” for the rest 8 segments. Referring to FIG. 14c, the waveform presented therein is turned “ON” for the first 3 (3=1+2) segments of the frame duration T and turned “OFF” for the rest 12 (12=4+8) segments.

Concurrent with the first waveform format, a second set of PWM waveforms, which is different from the first set of waveforms corresponding for driving the pixels to display desired grayscales, is generated. In the embodiment of the invention, a second set of PWM is generated based on a second PWM waveform format, as shown in FIG. 15. The second waveform format is a binary-weighted waveform format starting from the MSB and ending at the LSB. FIGS. 16a and 16b show two exemplary PWM waveforms generated based on such waveform format. Referring to FIG. 16a, the waveform is in “ON” state for the first 8 segments of the frame duration T and turned “OFF” for the rest 7 segments. Referring to FIG. 16b, the waveform is “OFF” for the first 12 segments of the frame duration T and turned “ON” for the rest 3 segments. The generated waveforms in FIGS. 14b, 14c, 16a, and 16b are applied concurrently for driving the pixels of the row of the micromirror array device.

The micromirror array device can be used in display and other suitable applications. FIG. 18 demonstratively illustrates an exemplary display system in which embodiments of the invention are implemented. Referring to FIG. 18, display system 280 comprises light source illumination system 292, spatial light modulator 290, projection lens 294, and display target 296. The illumination system may further comprise light source 282, light pipe 284, and color filter 286 such as a color wheel. Alternative to the illumination system 292 as shown in the figure wherein the color wheel is positioned after the light pipe along the propagation path of the illumination light from the light source, the color wheel can also be positioned between the light source and light pipe at the propagation path of the illumination light. The illumination light can be polarized or non-polarized. When polarized illumination light is used, display target 296 may comprise a polarization filter associated with the polarized illumination light, as set forth in U.S. provisional patent application Ser. No. 60/577,422 filed Jun. 4, 2004, the subject matter being incorporated herein by reference.

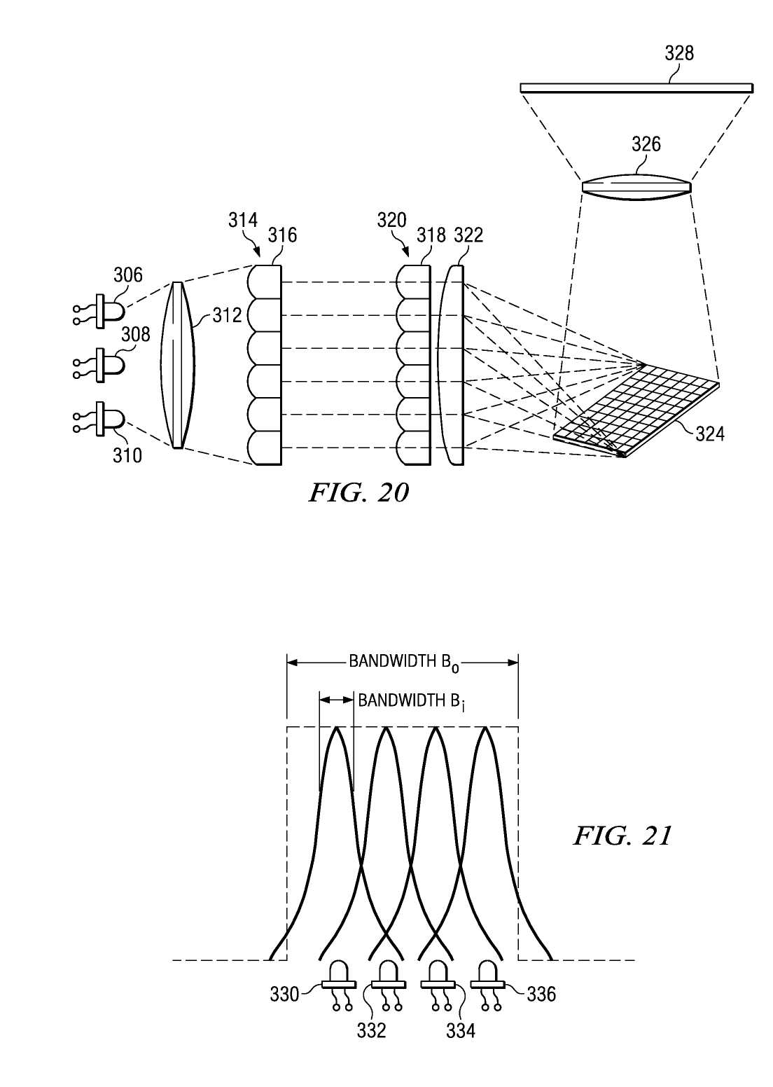

The light source can be any suitable light source, such as an arc lamp, preferably an arc lamp with a short arc for obtaining intensive illumination light. The light source can also be an arc lamp with a spiral reflector, as set forth in U.S. patent application Ser. No. 11/055,654 filed Feb. 9, 2005, the subject matter being incorporated herein by reference. Alternatively, the light source can be light-emission-diodes (LEDs), which will be detailed afterwards with reference to FIG. 20 and FIG. 21.

The lightpipe (284) can be a standard lightpipe that is widely used in digital display systems for delivering homogenized light from the light source to spatial light modulators. Alternatively, the lightpipe can be the one with movable reflective surfaces, as set forth in U.S. patent provisional application Ser. No. 60/620,395 filed Oct. 19, 2004, the subject matter being incorporated herein by reference.

The color wheel (286) comprises a set of color and/or white segments, such as red, green, blue, or yellow, cyan, and magenta. The color wheel may further comprise a clear or non-clear segment, such as a high throughput or white segment for achieving particular purposes, as set forth in U.S. patent application Ser. No. 10/899,637, and Ser. No. 10/899,635 both filed Jul. 26, 2004, the subject matter of each being incorporated herein by reference, which will not be discussed in detail herein.

It is noted that the color wheel and lightpipe may not be necessary, especially when a LED is employed as the light source.

The display system in FIG. 18 employs one spatial light modulator. However, a display system may use multiple spatial light modulators for modulating the illumination light of different colors. One of such display systems is schematically illustrated in FIG. 19. Referring to FIG. 19, the display system uses a dichroic prism assembly 298 for splitting incident light into three primary color light beams. Dichroic prism assembly comprises TIR 286a, 286c, 286d, 286e and 286f. Totally-internally-reflection (TIR) surfaces, i.e. TIR surfaces 296a and 296b, are defined at the prism surfaces that face air gaps. The surfaces 294a and 294b of prisms 286c and 286e are coated with dichroic films, yielding dichroic surfaces. In particular, dichroic surface 294a reflects green light and transmits other light. Dichroic surface 294b reflects red light and transmits other light. The three spatial light modulators, 288, 290 and 292, each having a micromirror array device, are arranged around the prism assembly.

In operation, incident white light from light source 282 enters into TIR 286a and is directed towards spatial light modulator 292, which is designated for modulating the blue light component of the incident white light. At the dichroic surface 294a, the green light component of the totally internally reflected light from TIR surface 296a is separated therefrom and reflected towards spatial light modulator 288, which is designated for modulating green light. As seen, the separated green light may experience TIR by TIR surface 296b in order to illuminate spatial light modulator 290 at a desired angle. This can be accomplished by arranging the incident angle of the separated green light onto TIR surface 294b larger than the critical TIR angle of TIR surface 296b. The rest of the light components, other than the green light, of the reflected light from the TIR surface 296a pass through dichroic surface 294a and are reflected at dichroic surface 294b. Because dichroic surface 294b is designated for reflecting red light component, the red light component of the incident light onto dichroic surface 294b is thus separated and reflected onto spatial light modulator 290, which is designated for modulating red light. Finally, the blue component of the white incident light reaches spatial light modulator 292 and is modulated thereby. By collaborating operations of the three spatial light modulators, red, green, and blue lights can be properly modulated. The modulated red, green, and blue lights are recollected and delivered onto display target 304 through optic elements, such as projection lens 302, if necessary.

As mentioned earlier, an LED can be used in the display system as the light source for providing illumination light beams due to many advantages, such as compact size, longer lifetime than arc lamps, lower heating than arc lamps, and narrower bandwidth than arc lamps. As an example, gallium nitride light emitting diodes can be used for the green and blue arrays, and gallium arsenide (aluminum gallium arsenide) could be used for the red light emitting diode array. LEDs such as available or disclosed by Nichia™ or Lumileds™ could be used, or any other suitable light emitting diodes. Some of the current LEDs have a lifetime of 100,000 hours or more, which is almost 10 times higher than the lifetime of the current UHP arc lamp with the longest lifetime. LEDs are cold light source, which yields much less heat than arc lamps. Even using multiple LEDs in a display system, the total heat generated by the LEDs can be dissipated much easier than using the arc lamps, because the heat generated by the LEDs is omni-directional as compared to the heat generated by the arc lamps wherein the heat has preferred orientations. Currently, LEDs of different colors have been developed. When multiple LEDs of different colors, such as red, green, and blue, are concurrently employed in the display system, beam splitting elements, such as color wheel, that are required for the arc lamp, can be omitted. Without light splitting elements, system design and manufacturing can be significantly simplified. Moreover, the display system can be made more compact and portable.

As compared to current arc lamps, LEDs are also superior in spectrum to arc lamps. The spectrum of a LED has a typical width of 10 nm to 35 nm. However, the typical spectrum width of the colors (e.g. red, green, and blue) derived from the color wheel used in combination with an arc lamp is approximately 70 nm, which is much larger than that of the LED. In other words, LEDs have much purer colors than arc lamps, resulting in more abundant colors than arc lamps.

Like arc lamps, LEDs may have the color balance problem, wherein different colors may have different intensities. This problem for LEDs, however, can be solved simply by time-mixing or spatial-mixing mode. In spatial-mixing mode, different number of LEDs for different colors can be provided for balancing the intensity discrepancies in different colors. In time-mixing mode, the color can be balanced by tuning the ON-time ratio of different LEDs for different colors, which will be detailed with reference to FIG. 20.

To be commensurate with the display system, the LEDs used in the projection system preferably have a light flux of 3 lumens or higher, such as 4.4 lumens or higher, and 11.5 lumens or higher.

Using multiple LEDs of different colors has other practical benefits as compared to using the arc lamp and color wheel. In the display system using the arc lamp and color wheel, color transition unavoidably occurs as the color wheel spins and color fields in the color wheel sequentially sweeps across the micromirror array of the spatial light modulator. The color transition cast extra design for the system, which complicate the system. Moreover, color transition reduces optical efficiency of the system, for example, a portion of the incident light has to be sacrificed. As a comparison, LEDs may not have the color transition problem. Regardless whether the LEDs sequentially or concurrently illuminate the micromirror devices of the spatial light modulator, all micromirror devices of the spatial light modulator can be illuminated by a light beam of specific color at a time.

Referring to FIG. 20, an exemplary display system using LEDs as light source is demonstratively illustrated therein. In this example, the projection system comprises a LED array (e.g. LEDs 306, 308, and 310) for providing illumination light beam for the system. For demonstration purposes only, three LEDs are illustrated in the figure. In practice, the LED group may have any suitable number of LEDs, including a single LED. The LEDs can be of the same color (e.g. white color) or different colors (e.g. red, green, and blue). The light beams from the LED array are projected onto front fly-eye lens 314 through collimation lens 312. Fly-eye lens 314 comprises multiple unit lenses such as unit lens 316. The unit lenses on fly-eye lens 314 can be cubical lens or any other suitable lenses, and the total number of the unit lenses in the fly-eye lens 316 can be any desired numbers. At fly-eye lens 314, the light beam from each of the LEDs is split into a number of sub-light beams with the total number being equal to the total number of unit lenses of fly-eye lens 314. After collimate lens 312 and fly-eye lens 314, each LED is imaged onto each unit lens (e.g. unit lens 318) of rear fly-eye lens 320. The rear fly-eye lens comprises a plurality of unit lenses each of which corresponds to one of the unit lenses of the front fly-eye lens 314, such that each of the LEDs forms an image at each unit lens of the rear fly-eye lens. Projection lens 322 projects the light beams from each unit lens of fly-eye lens 320 onto spatial light modulator 324.

With the above optical configuration, the light beams from the LEDs can be uniformly projected onto the micromirror devices of the spatial light modulator.

In the display system, a single LED can be used, in which instance, the LED preferably provides white color. Alternatively, an array of LEDs capable of emitting the same (e.g. white) or different colors (e.g. red, green, and blue) can be employed. Especially when multiple LEDs are employed for producing different colors, each color can be produced by one or more LEDs. In practical operation, it may be desired that different colors have approximately the same or specific characteristic spectrum widths. It may also be desired that different colors have the same illumination intensity. These requirements can be satisfied by juxtaposing certain number of LEDs with slightly different spectrums, as demonstratively shown in FIG. 21.

Referring to FIG. 21, it is assumed that the desired spectrum bandwidth of a specific color (e.g. red) is Bₒ (e.g. a value from 10 nm to 80 nm, or from 60 nm to 70 nm), and the characteristic spectrum bandwidth of each LED (e.g. LEDs 330, 332, 334, and 336) is Bᵢ (e.g. a value from 10 nm to 35 nm). By properly selecting the number of LEDs with suitable spectrum differences, the desired spectrum can be obtained. As a way of example, assuming that the red color with the wavelength of 660 nm and spectrum bandwidth of 60 nm is desired, LEDs 330, 332, 334, and 336 can be selected and juxtaposed as shown in the figure. LED 330, 332, 334, and 336 may have characteristic spectrum of 660 nm, 665 nm, 670 nm, and 675 nm, and the characteristic spectrum width of each LED is approximately 10 nm. As a result, the effective spectrum width of the juxtaposed LEDs can approximately be the desired red color with the desired spectrum width.

Different LEDs emitting different colors may exhibit different intensities, in which instance, the color balance is desired so as to generate different colors of the same intensity. An approach is to adjust the ratio of the total number of LEDs for the different colors to be balanced according to the ratio of the intensities of the different colors, such that the effective output intensities of different colors are approximately the same.

In the display system wherein LEDs are provided for illuminating a single spatial light modulator with different colors, the different colors can be sequentially directed to the spatial light modulator. For this purpose, the LEDs for different colors can be sequentially turned on, and the LEDs for the same color are turned on concurrently. Exemplary LEDs usable as light source for display systems can be those products by Luminuf, Inc.

Alternative to arc lamps and LEDs, a projection system may also use laser to provide illumination light. Specifically, the laser can provide white light, or primary colors, such as red, green, and blue, or yellow, magenta, and cyan. Exemplary laser sources usable as light source for display systems can be those products by Novalux Inc. (http://www.novalux.com/)

It will be appreciated by those of skill in the art that a new and useful memory cell array with robust accessing mechanism has been described herein. In view of the many possible embodiments to which the principles of this invention may be applied, however, it should be recognized that the embodiments described herein with respect to the drawing figures are meant to be illustrative only and should not be taken as limiting the scope of invention. For example, those of skill in the art will recognize that the illustrated embodiments can be modified in arrangement and detail without departing from the spirit of the invention. Although the invention is described with reference to DRAM memory cells in display systems employing SLM, those skilled in the art will recognize that such may be equivalently replaced by any suitable memory cells, such as charge-pump pixel cell (described patent application, Ser. No. 10/340,162, filed on Jan. 10, 2003 to Richards), SRAM or latch and optical switches using SLM. Though 4-bits binary-weighted PWM waveform formats are used in describing the embodiments of the invention, this should not be interpreted as limitations of the invention. For example, 128 bits or 256 bits weightings could be applied. Instead, any suitable PWM waveforms are applicable for driving the pixels of the display system. Therefore, the invention as described herein contemplates all such embodiments as may come within the scope of the following claims and equivalents thereof.

We claim:

1. A spatial light modulator device, comprising:
an array of reflective and deflectable mirror plates;
a plurality of addressing electrodes each of which is associated with one of the array of mirror plates;
an array of memory cells, each of which is connected to one of the array of addressing electrodes for controlling an electrostatic state of the addressing electrodes;
wherein each one of the memory cells is connected to a bitline and wordline; and
wherein each wordline is connected to two or more wordline drivers.

2. The device of claim 1, wherein each memory cell comprises:
a transistor with a source, gate, and drain;
a capacitor with first and second plates;
wherein the source of the transistor is connected to one of the bitlines;
wherein the gate is connected to one of the bitlines; and
wherein the drain is connected to the first plate of the capacitor so as to form a voltage node to which one of the addressing electrodes is connected.

3. The device of claim 2, wherein the second plate of the capacitor is connected to a pumping signal whose voltage varies over time during an operation.

4. The device of claim 1, wherein the memory cells of a row of the array are connected to a plurality of wordlines such that at least two memory cells of the row are connected to different wordlines.

5. The device of claim 4, wherein the even and odd numbered memory cells of the row are alternatively connected to first and second wordlines.

6. The device of claim 4, wherein the memory cells of the row are divided into a plurality of groups, wherein the memory cells in the same group are connected to the same wordline; and the memory cells in different groups are connected to different wordlines.

7. The device of claim 1, wherein the addressing electrodes and memory cells are formed on a semiconductor substrate; and wherein the mirror plates are formed on a light transmissive substrate.

8. The device of claim 7, wherein the light transmissive substrate further comprises an electrode that is transmissive to the visible light.

9. The device of claim 8, wherein said light transmissive electrode is common to all mirror plates in the array.

10. The device of claim 1, wherein the addressing electrodes, memory cells, and mirror plates are formed on a semiconductor substrate.

11. The device of claim 1, wherein each bitline is connected to a bitline driver.

12. The device of claim 11, wherein each bitline is connected to first and second bitline drivers that drive the bitline in opposite directions.

13. A method of operating an array of memory cells, each memory cell comprising a transistor and a capacitor, wherein the transistor comprises a source, a gate, and a drain; and wherein the capacitor comprises first and second plates, the method comprising:
grouping the memory cells in each row into a plurality of groups;
activating the memory cells in different groups with a plurality of different wordlines;
writing or reading the memory cells with bitlines;
alternating a voltage of each one of the second plates of the capacitors with a pump line that connects to the second plates of the capacitors so as to obtain a plurality of voltages at a plurality of voltage nodes, each node being formed by a connection of the first plate of the capacitor and the drain of the transistor; and
synchronizing the wordline and pump line that are connected to the same memory cell.

14. The method of claim 13, wherein the even number positioned memory cells in each row are connected to a first wordline; and wherein the odd number positioned memory cells in said each row are connected to a second wordline.

15. The method of claim 14, wherein the memory cells in different groups have the second plates of the capacitors connected to different pump lines.

16. The method of claim 13, wherein at least one of the wordlines is connected to first and second wordline drivers that drive said wordline in opposite directions.

17. The method of claim 13, wherein at least one of the pump lines is connect to first and second drivers for driving the pump line at opposite directions.

18. A projection system, comprising:
an illumination system providing light;
the spatial light modulator of claim 1 for modulating the light according to a set of image data derived from a desired image; and
an optical lens for projecting the modulated light onto a view area.

19. The projection system of claim 18, wherein the illumination system comprises an arc lamp.

20. The projection system of claim 18, wherein the illumination system comprises a LED.

21. The projection system of claim 20, wherein the illumination system comprises a set of LEDs capable of emitting a group of different colors.

22. The projection system of claim 21, wherein each color is generated by a plurality of LEDs of different spectra.

23. The projection system of claim 18, wherein the illumination system comprises a laser.

24. A device, comprising:
an array of memory cells connected to a plurality of wordlines and bitlines, wherein at least two memory cells in a row are connected to different wordlines; and
wherein at least one of the wordlines is connected to first and second wordline drivers for driving said wordline in opposite directions.

25. The device of claim 24, wherein at least one of the bitlines is connected to first and second bitline drivers for driving said bitline in opposite directions.

26. The device of claim 24, wherein each one of the bitlines is connected to one single bitline driver for driving said each one of the bitlines.

27. The device of claim 24, wherein the memory cells are connected to a plurality of pump lines; and wherein the wordline and pump line connecting the same memory cell are paired such that said wordline and pump line are dependent during a reading or writing of the memory cell.

28. The device of claim 27, wherein the memory cells connected to different wordlines are connected to different pump lines.

29. The device of claim 27, wherein at least one of the pump lines is connected to first and second pump line drivers for driving said pump line.

30. The device of claim 24, wherein each memory cell comprises a transistor and a capacitor, wherein the source of the transistor is connected to one of the bitlines, the gate is connected to one of the wordlines, and the drain is connected to one of the plates of the capacitor so as to form a voltage node.

31. The device of claim 30, wherein the other one of the plates of the capacitor is connected to one of the pump lines.

32. The device of claim 24, further comprising:
an array of addressing electrodes, each of which is connected to a voltage node of one of the memory cells; and
an array of reflective and deflectable mirror plates each of which is associated with one of the addressing electrodes such that the mirror plate is capable of being moved by an electrostatic field established between said mirror plate and associated addressing electrode.

33. The device of claim 32, wherein the mirror plates, addressing electrodes, and memory cells are formed on a semiconductor substrate.

34. The device of claim 32, wherein the addressing electrodes and memory cells are formed on a semiconductor substrate; and wherein the mirror plates are formed on a substrate that is transmissive to visible light.

35. A projection system, comprising:
an illumination system providing light;
the spatial light modulator of claim 24 for modulating the light according to a set of image data derived from a desired image; and
an optical lens for projecting the modulated light onto a view area.

36. The projection system of claim 35, wherein the illumination system comprises an arc lamp.

37. The projection system of claim 35, wherein the illumination system comprises a LED.

38. The projection system of claim 35, wherein the illumination system comprises a set of LEDs capable of emitting a group of different colors.

39. The projection system of claim 38, wherein each color is generated by a plurality of LEDs of different spectra.

40. The projection system of claim 35, wherein the illumination system comprises a laser.

41. A device, comprising:
an array of memory cells each of which comprises a transistor and a capacitor, wherein the gate of the transistor is connected to one of a plurality of wordlines, wherein the source of the transistor is connected to one of a plurality of bitlines, wherein the drain of the transistor is connected to one of the plates of the capacitor so as to form a voltage node, and wherein the other plate is connected to one of a plurality of pump lines whose voltage is capable of varying over time;
wherein at least one of the wordlines is connected to first and second wordline drivers for driving said wordline in opposite directions.

42. The device of claim 41, wherein at least two memory cells of a row of the array are connected to different wordlines.

43. The device of claim 42, wherein the memory cells connected to different wordlines are connected to different pump lines.

44. The device of claim 42, wherein at least one of the pump lines is connected to first and second drivers for driving said pump line.

45. The device of claim 41, wherein at least one of the bitlines is connected to first and second bitline drivers for driving said bitline in opposite direction.

46. The device of claim 41, wherein each one of the bitlines is connected to one single bitline driver for driving said each one of the bitlines.

47. The device of claim 41, further comprising:
an array of addressing electrodes, each of which is connected to a voltage node of one of the memory cells; and
an array of reflective and deflectable mirror plates each of which is associated with one of the addressing electrodes such that the mirror plate is capable of being moved by an electrostatic field established between said mirror plate and associated addressing electrode.

48. The device of claim 47, wherein the mirror plates, addressing electrodes, and memory cells are formed on a semiconductor substrate.

49. The device of claim 47, wherein the addressing electrodes and memory cells are formed on a semiconductor substrate; and wherein the mirror plates are formed on a substrate that is transmissive to visible light.

50. A projection system, comprising:
an illumination system providing light;
the spatial light modulator of claim 41 for modulating the light according to a set of image data derived from a desired image; and
an optical lens for projecting the modulated light onto a view area.

51. The projection system of claim 50, wherein the illumination system comprises an arc lamp.

52. The projection system of claim 50, wherein the illumination system comprises a LED.

53. The projection system of claim 50, wherein the illumination system comprises a set of LEDs capable of emitting a group of different colors.

54. The projection system of claim 53, wherein each color is generated by a plurality of LEDs of different spectra.

55. The projection system of claim 50, wherein the illumination system comprises a laser.
